(19) United States
(12) Patent Application Publication
(10) Pub. No.: US 2014/0266319 A1
(43) Pub. Date: Sep. 18, 2014

(54) CAPACITIVE HIGH PASS PRE-EMPHASIS CIRCUIT

(71) Applicant: TEXAS INSTRUMENTS DEUTSCHLAND GmbH, Freising (DE)

(72) Inventors: Alexander BODEM, Rodgau (DE); Robert C. TAFT, Munich (DE)

(73) Assignee: TEXAS INSTRUMENTS DEUTSCHLAND GmbH, Freising (DE)

(21) Appl. No.: 13/797,782

(22) Filed: Mar. 12, 2013

(51) Int. Cl. H03K 19/00

(52) U.S. Cl. CPC H03K 19/0005
USPC 327/108

(57) ABSTRACT

Some aspects of the disclosure are directed to a transmission circuit that includes a main driver. The transmission circuit also includes a plurality of capacitive modules connected in parallel to the main driver. A controller also is included that is coupled to the plurality of capacitive modules. The controller selectively enables and disables each capacitive module to implement a target amount of pre-emphasis.

### CROSS-REFERENCE TO RELATED APPLICATION

N/A.

### BACKGROUND

A high speed signal traveling along a long conductor (e.g., a trace on a printed circuit board) will degrade due to the electrical properties of the conductor. The higher the frequency of the signal and the longer the conductor length, the greater is the signal degradation. The conductor with dielectric is usually over a ground plane and the combined structure is referred to as a transmission line which generally has a low pass filter characteristic. The low pass filter characteristic of transmission lines may cause a degradation of high speed transmission signals, to the point at which such high speed signals may no longer satisfy the receiver's mask specification.

### SUMMARY

Some aspects are directed to a transmission circuit that includes a main driver connected in series to an output resistor. The transmission circuit also includes a plurality of capacitive modules connected in parallel to the main driver and output resistor. A controller also is included that is coupled to the plurality of capacitive modules. The controller selectively enables and disables each capacitive module to implement a target amount of pre-emphasis.

Yet other aspects are directed to a transmission circuit that includes a main driver connected in series to an output resistor, a controller, and a plurality of capacitive modules connected in parallel to the main driver and output resistor. Each capacitive module includes a NAND gate connected in series to an inverter and the inverter connected in series to a capacitor. The controller is coupled to the plurality of capacitive modules. Based on reading a value from a register, the controller selectively enables and disables each capacitive module to implement a target amount of pre-emphasis.

Another aspect is directed to method of configuring an amount of pre-emphasis in a transmission circuit. The method includes reading a value from storage, the value indicative of which of a plurality of capacitive modules coupled in parallel with a series combination of a main driver and output resistor. Based on the value, the method further includes selectively enabling and disabling each of the plurality of capacitive modules.

### BRIEF DESCRIPTION OF THE DRAWINGS

For a detailed description of exemplary embodiments of the invention, reference will now be made to the accompanying drawings in which:

FIG. 1 shows a system including a transmitter with a programmable high pass filter in accordance with principles disclosed herein;

FIG. 2 shows an example of the transmitter of FIG. 1 in accordance with principles disclosed herein;

FIG. 3 shows an example of a capacitive module usable in the transmitter of FIG. 2 in accordance with principles disclosed herein;

FIGS. 4A and 4B show a transmitter for a differential signal in accordance with principles disclosed herein;

FIG. 5 illustrates a resistor for test purposes in parallel with a capacitor in each capacitive module; and

FIGS. 6 and 7 show methods in accordance with principles disclosed herein.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

The low pass filter characteristic noted above may be addressed by imposing an amount of pre-emphasis on the signal before its transmission on the transmission line. Pre-emphasis may include implementing a high pass filter to boost targeted higher frequencies relative to lower frequencies to compensate for the degradation the signal will experience due to the transmission line. A transmitter may be used in a variety of applications to transmit signals of different data rates and across transmission lines of different lengths. The variability of the data rates and the transmission line length may make a fixed amount of pre-emphasis problematic. An amount of pre-emphasis for one application may be inadequate in a different application having a different data rate and/or transmission line length. Thus, in accordance with the principles disclosed herein, a transmitter with a programmable high pass filter is provided. The high pass filter of the transmitter may be programmable based on the data rate and length of the conductive lines on the printed circuit board or other substrate on which the transmitter is constructed. The high pass filter thus can be programmed to provide a target amount of pre-emphasis for the given transmission condition (data rate and transmission line length).

FIG. 1 illustrates a host 100 that provides a DATA signal for transmission by a transmitter 110 with a programmable high pass filter. The transmitter 110 includes a programmable high pass filter that is programmable via a CONTROL signal from the host 100. A register 102 in, or accessible by, the host 100 may include a value that in indicates how the high pass filter of the transmitter 110 is to be programmed to provide a target amount of pre-emphasis. Instead of a register 102, any suitable type of non-volatile storage can be used. The host 100 generates the CONTROL signal for the transmitter's filter based on the value contained in register 102. Multiple values are stored in the register 102 to permit the host to program various amounts of pre-emphasis in the transmitter's filter.

The high pass filter contained in the transmitter 110 may include one or more selectable capacitors that may be individually enabled to be operationally placed in parallel with a main output driver. FIG. 2 illustrates an example of the transmitter 110. As shown, the transmitter 110 includes a main output driver 114 connected in series to an output resistor 116 (e.g., a 50 ohm resistor), although output resistor 116 need not be included. The DATA signal of FIG. 1 is shown in FIG. 2 as the signal labeled “INPUT.” The INPUT signal is provided through driver 114 and series connected output resistor 116 as the signal labeled “OUTPUT.” Thus, the OUTPUT signal is the output of the transmitter 110 to be transmitted over a transmission line.

Connected in parallel with the series combination of main driver 114 and output resistor 116, are a plurality of capacitive modules 120. Each capacitive module 120 includes a capacitive element (e.g., a capacitor) and each capacitive module 120 may be individually enabled by the CONTROL signal from the host 100. In some aspects, the CONTROL signal includes multiple control signals—an individual control signal for each capacitive module 120. Via the CONTROL signals, any individual capacitive element may be enabled, or any combination of two or more capacitive modules 120 may be enabled. By enabling various capacitive modules 120, a programmable high pass filter is implemented. A capacitive module 120 that is not enabled, preferably is tristated.

A variable amount of pre-emphasis thus can be generated by enabling and disabling individual capacitance modules. The variable amount of pre-emphasis results in a high pass filter with a variable cut-off frequency. The various capacitance modules 120 are connected in parallel and thus the equivalent capacitance of the parallel arrangement of enabled capacitance modules increases as additional capacitance modules are enabled, and decreases with fewer enabled capacitance modules. A higher equivalent capacitance results in a lower cut-off frequency, and a lower equivalent capacitance results in a higher cut-off frequency.

FIG. 3 illustrates an implementation of a capacitive module 120. In the implementation shown, the capacitive module 120 includes a gate 130 connected to an inverter 132 which is connected to a capacitor 134. The gate 130 may any suitable type of logic gate such as a NAND gate, an AND gate, an XOR gate, a NOR gate, etc. In the implementation in FIG. 3, the gate 130 is illustrated as a NAND gate and will be discussed as such herein for simplicity, but the gate can be other than a NAND gate. The inverter 132 preferably is tristate inverter, although need not be a tristatable device. Further, inverter 132 could be a non-inverting buffer, but is illustrated as a tristate inverter for discussion purposes herein. Thus, each capacitive module 120 may include a series combination of a NAND gate followed by a tristate inverter followed by a capacitor.

The NAND gate 130 preferably has at least two inputs. The INPUT signal to be transmitted is provided to one of the inputs of the NAND gate as shown in FIG. 3. The CONTROL signal from FIGS. 1 and 2 is represented in the implementation of FIG. 3 as an ENABLE (EN) signal and the inverse of the EN signal (EN bar). The EN signal is provided to the other input of the NAND gate 130, as well as to the enable input of the tristate inverter 132. The EN bar signal is provided as an input to the inverse EN input of the tristate inverter 132. The output from the NAND gate 130 is provided to the input of the tristate inverter 132. When the tristate inverter 132 is enabled (EN high and EN bar low), the output signal from the inverter 132 is the inverse of its input. The output from the tristate inverter 132 is provided to the capacitor 134. When the tristate inverter 132 is disabled (EN low and EN bar high), the output of the inverter 132 is tristated (i.e., high impedance).

The truth table implemented by a NAND gate is that the output is the inverse of one input when the other input is at logic high level. Further, the output is forced to a logic high level when one of either input is at a logic low level. An individual capacitive module 120 may be selected by host 100 by way of a high level for the EN signal and a low logic level for EN bar. With EN high (which is provided to one input of the NAND gate 132) and EN bar low, due to the truth table of a NAND gate, the NAND gate 132 inverts the INPUT signal and the tristate inverter is enabled for functioning to invert its input from the NAND gate 130.

However, a capacitive module provided with EN low and EN bar high, that capacitive module 120 is disabled and thus not selected to operate as part of the high pass filter otherwise implemented by other capacitive modules that are selected. With EN low, the output of the NAND gate 130 is forced to a logic high state regardless of the INPUT signal. Further, with EN low and EN bar high, the tristate inverter 132 is tristated (high impedance output state). By driving the tristate inverter 132 with a NAND gate, the leakage current through the inverter is reduced or eliminated compared to what otherwise would be the case if a gated buffer was provided on the other side of the capacitor. A NAND gate 130, with its output forced to a high steady state level, shields the tristate inverter 132 from any high frequencies that might be present on the INPUT signal.

The capacitors 134 in the various capacitive modules 120 may all be of the same capacitance in some implementations. However, in other implementations, one or more or all of the capacitors are different. For example, the various capacitors 134 among the capacitive modules 120 may have capacitance values that are binary weighted, such as is the case for the example of FIGS. 4a and 4b described below.

FIGS. 4a and 4b shows an example of a transmitter 150. The implementation of FIGS. 4a and 4b is a transmitter for a differential signal (INPUT and INPUT bar). The top portion 155 of the transmitter is for the INPUT signal and its programmable high pass filter, and the bottom portion 175 is for the INPUT bar signal and its programmable high pass filter.

The top portion 155 of FIG. 4a includes four capacitive modules 152, 154, 156, and 158. Each capacitive module 152-158 is configured similar to what is shown in FIG. 3 including the series combination of NAND gate 130, tristate inverter 132, and capacitor 134. The capacitors 134 of the various capacitive modules 152-158 are binary weighted. In the example of FIGS. 4a and 4b, the capacitor 134 of capacitive module 152 has a capacitance of 1 C (one unit of capacitance). The capacitor of capacitance module 154 has a capacitance of 2 C (i.e., twice the capacitance of the capacitor of the previous capacitance module 152. The capacitor of capacitance module 156 has a capacitance of 4 C (four times the capacitance of the capacitor of capacitance module 152). Finally, the capacitor of capacitance module 158 has a capacitance of 8 C (eight times the capacitance of the capacitor of capacitance module 152).

With binary weighted capacitors of 1 C, 2 C, 4 C, and 8 C and because the equivalent capacitance of capacitors connected in parallel is the sum of their capacitances, the host 100 can program the high filter for any capacitance from 1 C to 15 C in 1 C increments. For example, if a capacitance of 5 C is desired, then the host 100 asserts the CONTROL (EN signals) to enable only capacitance modules 156 and 152 (4 C and 1 C, respectively, for an equivalent capacitance of 5 C) while disabling the remaining capacitance modules 154 and 158.

The various tristate inverters 132 may all be of the same strength in some implementations, but be of different strengths in other implementations. For example, a tristate inverter connected to a larger capacitance may have a higher drive strength than an inverter connected to a lower capacitance. The tristate inverters 132 thus may be scaled to the various capacitors 134.

The main driver 114 of FIG. 2 is implemented in FIGS. 4a and 4b as an inverter 144 followed by a tristate inverter 146. Output resistor 148 (e.g., 50 ohms) is also shown. The various capacitance modules 152-158 are connected in parallel with the series combination of inverters 144 and 146 and resistor 148. The tristate function of the inverter 146 can be used for test purposes or to disable the output driver to use the output as an input.

The lower portion 175 of FIG. 4b is similar to the top portion but functions to transmit the inverse of the INPUT signal. The main driver in the lower portion 175 is shown by the series combination of inverter 184, tristate 186 and output resistor 188 (e.g., 50 ohms). The lower portion 175 also includes four capacitance modules shown as modules 162-168. Each capacitance module 162-168 is configured similar to a corresponding capacitance module of the upper portion 155 and the various capacitors are also binary weighted (1 C, 2 C, 4 C, and 8 C) as shown and as described above. Preferably for whichever capacitance modules 152-158 are enabled by host in the upper portion 155, the host also enables the corresponding capacitance modules 162-168 in the lower portion 175.

In the example of FIGS. 4a and 4b, a pair of resistors 190 and 192 is included connected between the OUTPUT signal from the upper portion 155 and the OUTPUT bar signal from the lower portion 175. The combination of resistors 148, 188, 190, and 192 is responsible for defining the voltages for the logic low and logic high states in order to comply with the applicable transmitting protocol specification.

A capacitor 134 is shown in FIGS. 3, 4a and 4b as being driven by each tristate inverter 132. FIG. 5 shows an implementation in which a resistor 135 is connected in parallel with each capacitor 134. The resistors 135 advantageously permit the functionality of the NAND gates 130 and inverters 132 to be verified with direct current (DC) tests. The resistance value of resistors 135 should be large to provide a high enough impedance so as not to interfere with the overall performance of the circuit, but low enough to be able to conduct enough current to be measured. The value of the resistance if of resistors 135 is application specific. A DC test voltage (high and/or low) can be imposed on the INPUT to gates 130 and the current through resistors 135 can be measured to verify that the gate 130 and inverter 132 functioning correctly.

FIG. 6 shows a method of programming the register 102 of FIG. 1. As illustrated in FIG. 6, an empirical study is performed at 202 to determine the amount of pre-emphasis that is suitable for various conditions. The various conditions include such factors as data rate, line length, etc. Once the right amount of pre-emphasis is determined for various conditions that may be experienced during runtime, the correct amount of pre-emphasis for the various conditions is provided (204) for subsequent use in programming register 102. For example, the pre-emphasis programming information may be provided on a specification sheet (or other suitable medium) corresponding to the transmitter 110. In some implementations, each specified pre-emphasis amount is a binary value. For the example of FIG. 4, which includes four capacitive modules 120 with binary weighted capacitors of 1 C, 2 C, 4 C, and 8 C, the binary value to be programmed into the register for a given transmission condition is a binary value in the range of 0 to 15. A value of 0 means no pre-emphasis. Values of 1 to 15 refer to capacitances of 1 C to 15 C.

FIG. 7 illustrates a method by which the high pass filter of the transmitter is programmed. At 210, the method comprises determining the conditions for a given application. This operation may entail determining the intended data rate, measuring line lengths of conductive traces, etc. At 212, based on the conditions determined at 210, the method further comprises reading a value from the register 102 that corresponds to the particular condition. The value read from the register is indicative of which capacitive modules are to be enabled. Based on the value read from the register 102, the target capacitive module(s) is(are) enabled (214) to implement the correct amount of pre-emphasis. In the example in which the register value is a binary value in the range of 0 to 15, the host 100 asserts the various CONTROL (EN, EN bar) signals to implement the binary weighted capacitors corresponding to the register value.

The example of FIG. 4 above illustrates four capacitive modules for each side of the differential signal to be transmitted and thus binary weights of 1 C, 2 C, 4 C, and 8 C are used. In other example, any number of capacitive modules and binary weighted capacitors are possible.

For example, if the register value is 3 (meaning 3 C), the host asserts the CONTROL signals to enable capacitive modules 152 and 154 in FIG. 4 and disable capacitive modules 156 and 158 for the upper portion 155, and enable capacitive modules 162 and 164 for the lower portion 175 and disable capacitive modules 166 and 168. Enabled capacitive modules 152 and 154 (and 162 and 164) have binary weighted capacitors of 1 C and 2 C, respectively, for an equivalent capacitance of 3 C.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A transmission circuit, comprising:
a main driver;
a plurality of capacitive modules connected in parallel to the main driver;
a controller coupled to the plurality of capacitive modules to selectively enable and disable each capacitive module to implement a target amount of pre-emphasis.

2. The transmission circuit of claim 1 wherein each capacitive module comprises a gate and a capacitor, and the gate includes an enable/disable input driven by a signal from the controller.

3. The transmission circuit of claim 2 wherein the gate comprises a NAND gate.

4. The transmission circuit of claim 2 wherein an output from the gate couples to the capacitor.

5. The transmission circuit of claim 2 wherein each capacitive module further includes a tristate inverter, and wherein an output from the gate connects to an input of the tristate inverter, and an output of the tristate inverter connects to the capacitor.

6. The transmission circuit of claim 4 wherein the gate comprises a NAND gate.

7. The transmission circuit of claim 1 further comprising a programmable non-volatile storage containing a value indicative of the number of capacitive modules that are to be activated by the controller.

8. The transmission circuit of claim 1 wherein the capacitance modules include binary weighted capacitors.

9. The transmission circuit of claim 8 further comprising a programmable non-volatile storage containing a binary value corresponding to binary weights of the binary weighted capacitors.

10. The transmission circuit of claim 1 wherein each capacitive module includes a capacitor connected in parallel with a resistor usable during testing,

11. The transmission circuit of claim 1 further including an output resistor connected in series to the main driver, and wherein the a plurality of capacitive modules are connected in parallel to the series combination of the main driver and output resistor.

12. A transmission circuit, comprising:
a main driver connected in series to an output resistor;
a plurality of capacitive modules connected in parallel to the main driver and output resistor, each capacitive module including a NAND gate connected in series to an inverter and the inverter connected in series to a capacitor;
a controller coupled to the plurality of capacitive modules, wherein the controller, based on reading a value from a register, is to selectively enable and disable each capacitive module to implement a target amount of pre-emphasis.

13. The transmission circuit of claim 12, wherein each inverter is a tristate inverter.

14. The transmission circuit of claim 12 wherein the capacitance modules include binary weighted capacitors.

15. The transmission circuit of claim 14 further comprising a programmable non-volatile storage containing a binary value corresponding to binary weights of the binary weighted capacitors.

16. The transmission circuit of claim 12 further comprising non-volatile storage containing a value indicative of the number of capacitive modules that are to be activated by the controller.

17. The transmission circuit of claim 12 wherein each capacitive module includes a resistor connected in parallel to that module's capacitor and usable during testing.

18. A method of configuring an amount of pre-emphasis in a transmission circuit, comprising:
reading a value from storage, the value indicative of certain of a plurality of capacitive modules coupled in parallel with a main driver;
based on the value, selectively enabling and disabling each of the plurality of capacitive modules.

19. The method of claim 18 further comprising determining a condition for a circuit and programming the storage to include the value based on the condition.
